(19) United States
(12) Patent Application Publication
(10) Pub. No.: US 2023/0376032 A1
(43) Pub. Date: Nov. 23, 2023

(54) REMOTE OPERATION SYSTEM AND REMOTE OPERATOR TERMINAL

(71) Applicant: Woven Planet Holdings, Inc., Tokyo (JP)

(72) Inventor: Toshinobu WATANABE, Tokyo-to (JP)

(73) Assignee: Woven Planet Holdings, Inc., Tokyo (JP)

(21) Appl. No.: 18/185,545

(22) Filed: Mar. 17, 2023

(30) Foreign Application Priority Data
May 17, 2022 (JP) 2022-081003

(51) Int. Cl. G05D 1/00; G06F 30/20

(52) U.S. Cl. CPC G05D 1/0038; G06F 30/20

(57) ABSTRACT

A remote operation system includes: a moving body being a target of a remote operation performed by a remote operator; and a remote operator terminal the remote operator side. The remote operator terminal includes a simulator executing in real time a simulation of an object group including the moving body in a predetermined space, and is configured to display a result of the simulation. In parallel with execution of the simulation, the remote operator terminal is further configured to: perform a communication with at least the moving body to receive object information indicating at least a position of the object group; execute a delay compensation process that compensates for a delay of the received object information to acquire corrected object information; and execute a synchronization process that corrects simulation object information, which is the object information in the simulation, based on the corrected object information.

### CROSS-REFERENCE TO RELATED APPLICATION

This application claims priority to Japanese Patent Application No. 2022-081003 filed on May 17, 2022, the entire contents of which are incorporated by reference herein.

### BACKGROUND

### Technical Field

The present disclosure relates to a technique for supporting a remote operation of a moving body performed by a remote operator.

### Background Art

Patent Literature 1 discloses a control device for remotely operating an operation target object. The control device communicates with an information providing means to acquire information on a type and a position of an object existing around the operation target object. Furthermore, the control device determines a virtual object for representing the object based on the acquired information on the type and the position of the object. Then, the control device displays the virtual object at a display position corresponding to a geographical position of the object. At this time, the control device estimates a future position of the object in consideration of a communication delay and corrects the display position of the virtual object.

Patent Literature 2 discloses a remote operation system that enables even an inexperienced operator to remotely operate a moving body easily.

In a field of metrology, a Kalman filter is generally known. The Kalman filter estimates a state of a system from measurement data. However, there is a gap between a data measurement timing and an operation timing of the Kalman filter, and the estimation accuracy decreases as the gap increases.
Non-Patent Literature 1 and Non-Patent Literature 2 disclose a “delayed Kalman filter” that can be applied to measurement data including a delay. The delayed Kalman filter is also called OOSM (Out-of-Sequence Measurement).

### LIST OF RELATED ART

Patent Literature 1: Japanese Laid-Open Patent Application No. JP-2020-167551
Patent Literature 2: Japanese Laid-Open Patent Application No. JP-2010-128935
Non-Patent Literature 1: Yaakov Bar-Shalom, “Update with Out-of-Sequence Measurements in Tracking: Exact Solution,” IEEE Transactions on Aerospace and Electronic Systems, VOL. 38, No. 3, pp. 769-778, July 2002.
Non-Patent Literature 2: Keshu Zhang et al., “Optimal Update with Out-of-Sequence Measurements,” IEEE Transactions on Signal Process, Vol. 53, No. 6, pp. 1992-2004, June 2005.

### SUMMARY

A remote operation of a moving body (e.g., a vehicle, a robot) performed by a remote operator is considered. During the remote operation, the moving body and a remote operator terminal on the remote operator side communicate with each other, and the communication is accompanied by a communication delay. The communication delay may cause a delay in decision by the remote operator, an awkward remote operation, and the like. In some case, the moving body may meander. It is therefore important to suppress an influence of the communication delay in the remote operation.

Moreover, information transmitted from the moving body to the remote operator terminal may be lost on the communication path. The information loss during the communication may also cause a delay in decision by the remote operator, an awkward remote operation, and the like. Therefore, it is also important to suppress an influence of the information loss in the remote operation.

An object of the present disclosure is to provide a technique capable of suppressing an influence of a communication delay and information loss during communication in a remote operation of a moving body performed by a remote operator.

A first aspect relates to a remote operation system.

The remote operation system includes:

a moving body being a target of a remote operation performed by a remote operator; and

a remote operator terminal on a side of the remote operator.

The remote operator terminal includes a simulator executing in real time a simulation of an object group including the moving body in a predetermined space, and is configured to display a result of the simulation.

In parallel with execution of the simulation, the remote operator terminal further executes the following processes.

The remote operator terminal performs a communication with at least the moving body to receive object information indicating at least a position of the object group. The remote operator terminal executes a delay compensation process that compensates for a delay of the received object information to acquire corrected object information. Further, the remote operator terminal executes a synchronization process that corrects simulation object information, which is the object information in the simulation, based on the corrected object information.

A second aspect relates to a remote operator terminal used by a remote operator performing a remote operation of a moving body.

The remote operator terminal includes one or more processors.

The one or more processors are configured to: execute in real time a simulation of an object group including the moving body in a predetermined space; and display a result of the simulation.

In parallel with execution of the simulation, the one or more processors further execute the following processes.

The one or more processors perform a communication with at least the moving body to receive object information indicating at least a position of the object group. The one or more processors execute a delay compensation process that compensates for a delay of the received object information to acquire corrected object information. Further, the one or more processors execute a synchronization process that corrects simulation object information, which is the object information in the simulation, based on the corrected object information.

According to the present disclosure, the remote operator terminal executes in real time the simulation of the object group including the moving body being the target of the remote operation. The remote operator terminal displays the result of the simulation. The remote operator is able to perform the remote operation of the moving body by referring to the displayed result of the simulation.

The simulation executed in the remote operator terminal does not depend on a condition of the communication between the moving body and the remote operator terminal. Thus, the remote operator is able to perform the remote operation of the moving body without being affected by the communication delay and the information loss. As a result, a delay in decision by the remote operator, an awkward remote operation, and the like are suppressed. That is, the remote operator is able to perform the remote operation of the moving body more smoothly and more safely.

Furthermore, the remote operator terminal receives the object information on the object group being the simulation target in parallel with execution of the simulation. The object information indicates at least the position of the object group. The remote operator terminal compensates for the delay of the received object information to acquire the corrected object information. Further, the remote operator terminal corrects the simulation object information based on the corrected object information. Thus, simulation accuracy is secured and accuracy of the remote operation is also secured.

### BRIEF DESCRIPTION OF DRAWINGS

FIG. 1 is a schematic diagram showing a configuration example of a remote operation system according to an embodiment of the present disclosure;

FIG. 2 is a block diagram for explaining a first mode of a remote operation system according to an embodiment of the present disclosure;

FIG. 3 is a block diagram for explaining a second mode of a remote operation system according to an embodiment of the present disclosure;

FIG. 4 is a schematic diagram showing an example of a simulation result screen displayed on a display device according to an embodiment of the present disclosure;

FIG. 5 is a block diagram showing a configuration example of a vehicle according to an embodiment of the present disclosure;

FIG. 6 is a block diagram showing a configuration example of a remote operator terminal according to an embodiment of the present disclosure;

FIG. 7 is a block diagram for explaining a simulator according to an embodiment of the present disclosure;

FIG. 8 is a block diagram showing a functional configuration example of a remote operator terminal in a second mode according to an embodiment of the present disclosure;

FIG. 9 is a conceptual diagram for explaining a delay in a remote operation system;

FIG. 10 is a conceptual diagram for explaining a delay compensation process;

FIG. 11 is a conceptual diagram for explaining a delay compensation process and an upsampling process;

FIG. 12 is a block diagram showing a first example of a delay compensation unit in a remote operator terminal according to an embodiment of the present disclosure;

FIG. 13 is a block diagram showing a second example of a delay compensation unit in a remote operator terminal according to an embodiment of the present disclosure;

FIG. 14 is a block diagram for explaining a switching process in a remote operator terminal according to an embodiment of the present disclosure;

FIG. 15 is a block diagram showing a functional configuration example related to a delay compensation process in a vehicle according to an embodiment of the present disclosure; and

FIG. 16 is a block diagram showing a configuration example of a delay compensation unit in a vehicle according to an embodiment of the present disclosure.

### EMBODIMENTS

Embodiments of the present disclosure will be described with reference to the accompanying drawings.

### 1. Overview of Remote Operation System

A remote operation (remote driving) of a moving body is considered. Examples of the moving body being a target of the remote operation include a vehicle, a robot, a flying object, and the like. The vehicle may be an autonomous driving vehicle or may be a vehicle driven by a driver. Examples of the robot include a logistics robot, a work robot, and the like. Examples of the flying object include an airplane, a drone, and the like.

As an example, in the following description, a case where the moving body being the target of the remote operation is a vehicle will be considered. When generalizing, “vehicle” in the following description shall be deemed to be replaced with “moving body.”

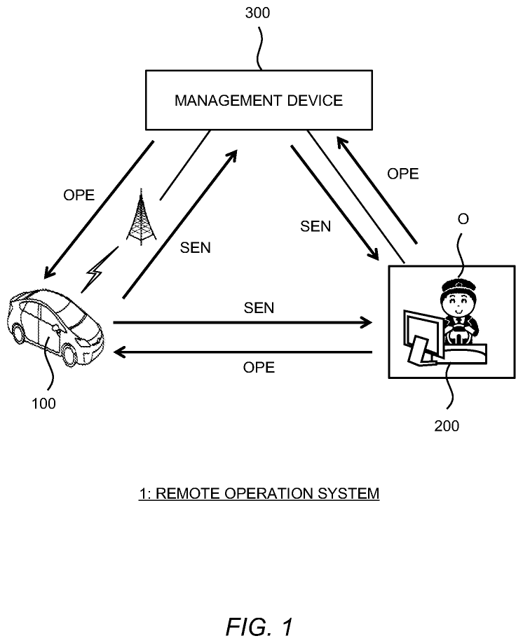

FIG. 1 is a schematic diagram showing a configuration example of a remote operation system 1 according to the present embodiment. The remote operation system 1 includes a vehicle 100, a remote operator terminal 200, and a management device 300. The vehicle 100 is the target of the remote operation. The remote operator terminal 200 is a terminal device used by a remote operator O when remotely operating the vehicle 100. The remote operator terminal 200 can also be referred to as a remote operation human machine interface (HMI). The management device 300 manages the remote operation system 1. Typically, the management device 300 is a management server on a cloud. The management server may be configured by a plurality of servers that perform distributed processing.

The vehicle 100, the remote operator terminal 200, and the management device 300 are capable of communicating with each other via a communication network. The vehicle 100 and the remote operator terminal 200 can communicate with each other via the management device 300. The vehicle 100 and the remote operator terminal 200 may directly communicate with each other without through the management device 300.

Various sensors including a camera are installed on the vehicle 100. The camera acquires image information indicating a situation around the vehicle 100. Sensor-detected information SEN includes information acquired by the various sensors. The sensor-detected information SEN includes at least the image information captured by the camera. The sensor-detected information SEN may include a position and a state (for example, a speed, a steering angle, and the like) of the vehicle 100. The vehicle 100 transmits the sensor-detected information SEN to the remote operator terminal 200.

The remote operator terminal 200 receives the sensor-detected information SEN transmitted from the vehicle 100. The remote operator terminal 200 presents the sensor-detected information SEN to the remote operator O. More specifically, the remote operator terminal 200 includes a display device, and displays the image information and the like on the display device. The remote operator O views the displayed information, recognizes the situation around the vehicle 100, and performs the remote operation of the vehicle 100. Remote operation information OPE is information relating to the remote operation performed by the remote operator O. For example, the remote operation information OPE includes an amount of operation performed by the remote operator O. The remote operator terminal 200 transmits the remote operation information OPE to the vehicle 100.

The vehicle 100 receives the remote operation information OPE transmitted from the remote operator terminal 200. The vehicle 100 performs vehicle travel control in accordance with the received remote operation information OPE. In this manner, the remote operation of the vehicle 100 is realized.

### 2. Multiple Modes of the Remote Operation System

As operation modes of the remote operation system 1 (in particular, the remote operator terminal 200), the following two types, a “first mode” and a “second mode” are considered.

### 2-1. First Mode

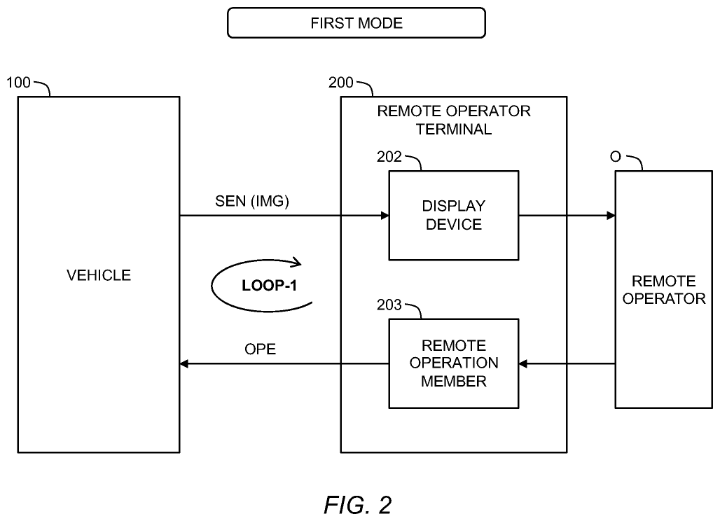

FIG. 2 is a block diagram for explaining the first mode. The first mode is a general mode.

The vehicle 100 transmits the sensor-detected information SEN acquired by the sensors to the remote operator terminal 200. The sensor-detected information SEN includes the image information IMG captured by the camera mounted on the vehicle 100. The remote operator terminal 200 receives the sensor-detected information SEN transmitted from the vehicle 100 and displays the image information IMG and the like on a display device 202. The remote operator O operates a remote operation member 203 to perform the remote operation of the vehicle 100 while viewing the displayed information. The remote operation information OPE includes information reflecting the amount of operation of the remote operation member 203 performed by the remote operator O. The remote operator terminal 200 transmits the remote operation information OPE to the vehicle 100. The vehicle 100 performs vehicle travel control in accordance with the remote operation information OPE received from remote operator terminal 200.

In this manner, in the first mode, a “first loop LOOP-1” including the communication between the vehicle 100 and the remote operator terminal 200 is formed.

However, the communication between the vehicle 100 and the remote operator terminal 200 is accompanied by a communication delay. The communication delay may cause a delay in decision by the remote operator O, an awkward remote operation, and the like. In some case, the vehicle 100 may meander. It is therefore important to suppress an influence of the communication delay in the remote operation.

Moreover, information transmitted from the vehicle 100 to the remote operator terminal 200 may be lost on the communication path. The information loss during the communication may also cause a delay in decision by the remote operator O, an awkward remote operation, and the like. Therefore, it is also important to suppress an influence of the information loss in the remote operation.

### 2-2. Second Mode

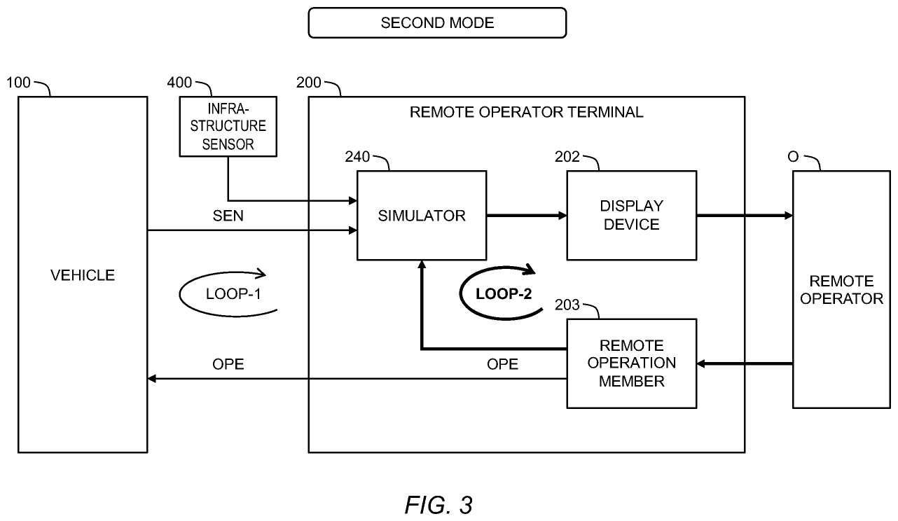

FIG. 3 is a block diagram for explaining the second mode. The second mode is a mode capable of suppressing the influence of the communication delay and the information loss during the communication.

More specifically, in the second mode, a “simulator 240” installed in the remote operator terminal 200 is used. The simulator 240 executes in real time a simulation of an object group including the vehicle 100 in a predetermined space. Typically, the predetermined space is a space of a fixed area. For example, the predetermined space is a “certain city” such as a smart city. The object group being the simulation target may include an obstacle 500 around the vehicle 100 in addition to the vehicle 100. In particular, the object group may include a moving obstacle 500. Examples of the obstacle 500 include another vehicle (a preceding vehicle, an adjacent vehicle, a following vehicle, and the like), a motor bike, a bicycle, a pedestrian, and the like. Such the simulator 240 is realized by, for example, a digital twin technique.

The sensor-detected information SEN includes “object information OBJ” regarding the object group being the simulation target. The object information OBJ indicates at least a position (an actual position in the predetermined space) of each object included in the object group. The object information OBJ may indicate a state (e.g., a speed, a steering angle, and the like) of each object included in the object group.

More specifically, the object information OBJ includes “vehicle information VCL” regarding the vehicle 100. The vehicle information VCL indicates at least a position of the vehicle 100 in the predetermined space. The vehicle information VCL may indicate a state (e.g., a speed, a steering angle, and the like) of the vehicle 100. Such the vehicle information VCL is acquired by the sensors mounted on the vehicle 100 and is provided from the vehicle 100 to the remote operator terminal 200.

The object information OBJ may include “obstacle information OBS” regarding each obstacle 500 around the vehicle 100. The obstacle information OBS indicates at least a position of the obstacle 500 in the predetermined space. The obstacle information OBS may indicate a state (e.g., a speed, a steering angle, and the like) of the obstacle 500. Such the obstacle information OBS is observed by the sensors mounted on the vehicle 100, for example, and is provided from the vehicle 100 to the remote operator terminal 200. As another example, the obstacle information OBS may be observed by an infrastructure sensor 400 (for example, an infrastructure camera) disposed in the predetermined space, and may be provided from the infrastructure sensor 400 to the remote operator terminal 200.

During the remote operation of the vehicle 100, the remote operator terminal 200 uses the simulator 240 to perform the simulation of the object group in the predetermined space. More specifically, an initial value of each object in the simulation is set based on the above-described object information OBJ included in the sensor-detected information SEN. After the initialization, the remote operator terminal 200 executes in real time the simulation of the object group in the predetermined space to estimate (predict) the object information OBJ. Then, the remote operator terminal 200 displays a result of the simulation on the display device 202 in real time.

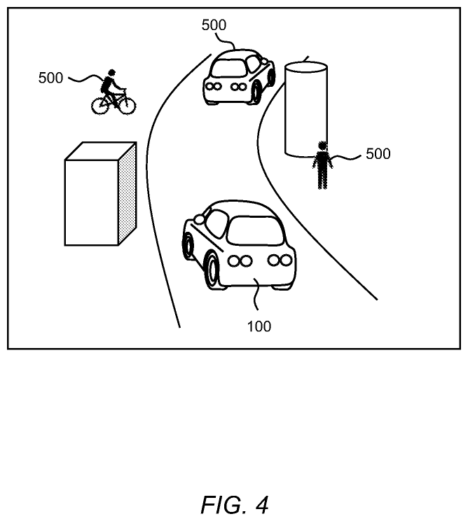

FIG. 4 shows an example of a simulation result screen displayed on the display device 202. The simulation result screen visually represents the object group (i.e., the vehicle 100 and the obstacle 500) in the predetermined space. For example, the simulation result screen three dimensionally represents the object group and a background in the predetermined space. The simulation result screen may reproduce and represent a view as seen from the vehicle 100. The simulation result screen is updated at each simulation cycle.

The remote operator O operates the remote operation member 203 to perform the remote operation of the vehicle 100 while viewing the simulation result screen displayed on the display device 202 in real time. The remote operation information OPE includes information reflecting the amount of operation of the remote operation member 203 performed by the remote operator O. The remote operation information OPE is transmitted to the vehicle 100 and reflected in the vehicle travel control. In addition, the remote operation information OPE is also fed back to the simulator 240. The simulator 240 reflects the amount of operation performed by the remote operator O in the simulation. That is, the simulator 240 executes the simulation while reflecting the amount of operation performed by the remote operator O in the object information OBJ (in particular, the vehicle information VCL) in the simulation.

As described above, in the second mode, the simulation of the object group including the vehicle 100 being the target of the remote operation is executed in the remote operator terminal 200. The simulation result is displayed on the display device 202, and the amount of operation performed by the remote operator O is fed back to the simulation. That is, a “second loop LOOP-2” is formed between the simulator 240 in the remote operator terminal 200 and the remote operator O (see FIG. 3). The second loop LOOP-2 does not include the communication between the vehicle 100 and the remote operator terminal 200. Therefore, the remote operation based on the second loop LOOP-2 does not depend on a condition of the communication, and thus is not affected by the communication delay and the information loss.

However, the simulation executed by the simulator 240 is accompanied by a simulation error. In order to correct the simulation error, the above-described first loop LOOP-1, that is, the sensor-detected information SEN is used. More specifically, the sensor-detected information SEN includes the object information OBJ regarding the object group being the simulation target. The object information OBJ indicates at least the position (the actual position in the predetermined space) of each object included in the object group. The object information OBJ may indicate the state (e.g., a speed, a steering angle, and the like) of each object included in the object group. Synchronizing the simulation result with the object information OBJ makes it possible to eliminate the simulation error. That is, in parallel with the execution of the simulation, the remote operator terminal 200 corrects the simulation result based on the object information OBJ received through the communication. As a result, simulation accuracy is secured and accuracy of the remote operation is also secured.

It should be noted that a communication cycle of the sensor-detected information SEN is longer than a simulation cycle of the simulator 240 in the remote operator terminal 200. In other words, a simulation frequency of the simulator 240 in the remote operator terminal 200 is higher than a communication frequency of the sensor-detected information SEN. Therefore, basically, the remote operator terminal 200 repeatedly executes the simulation based on the second loop LOOP-2 without using the sensor-detected information SEN. When receiving the sensor-detected information SEN through the communication, the remote operator terminal 200 appropriately corrects the simulation result based on the received sensor-detected information SEN (the object information OBJ).

### 2-3. Effects

According to the present embodiment, the above-described second mode is preferentially used. As a result, the following effects can be obtained.

The remote operator terminal 200 includes the simulator 240 that executes in real time the simulation of the object group including the vehicle 100 being the target of the remote operation. The remote operator terminal 200 displays the result of simulation on the display device 202. The remote operator O is able to perform the remote operation of the vehicle 100 by referring to the displayed result of the simulation.

The simulation (the second loop LOOP-2) executed in the remote operator terminal 200 does not depend on a condition of the communication between the vehicle 100 and the remote operator terminal 200. Therefore, the remote operator O is able to perform the remote operation of the vehicle 100 without being affected by the communication delay and the information loss. As a result, a delay in decision by the remote operator O, an awkward remote operation, and the like are suppressed. That is, the remote operator O is able to perform the remote operation of the vehicle 100 more smoothly and more safely.

Furthermore, according to the present embodiment, the remote operator terminal 200 receives the object information OBJ on the object group being the simulation target in parallel with the execution of the simulation. The object information OBJ indicates at least the position of the object group. The remote operator terminal 200 corrects the simulation result based on the object information OBJ. As a result, the simulation accuracy is secured and the accuracy of the remote operation is also secured.

### 3. Example of Vehicle

### 3-1. Configuration Example

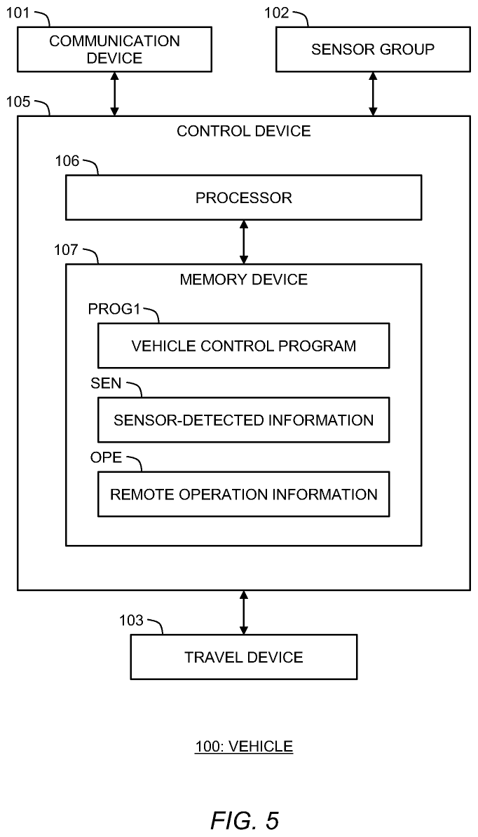

FIG. 5 is a block diagram showing a configuration example of the vehicle 100. The vehicle 100 includes a communication device 101, a sensor group 102, a travel device 103, and a control device (controller) 105.

The communication device 101 communicates with the outside of the vehicle 100. For example, the communication device 101 communicates with the remote operator terminal 200 and the management device 300.

The sensor group 102 includes a recognition sensor, a vehicle state sensor, a position sensor, and the like. The recognition sensor recognizes (detects) a situation around the vehicle 100. Examples of the recognition sensor include the camera, a laser imaging detection and ranging (LIDAR), a radar, and the like. The vehicle state sensor detects a state of the vehicle 100. Examples of the vehicle state sensor include a speed sensor, an acceleration sensor, a yaw rate sensor, a steering angle sensor, and the like. The position sensor detects a position and an orientation of the vehicle 100. For example, the position sensor includes a global navigation satellite system (GNSS).

The travel device 103 includes a steering device, a driving device, and a braking device. The steering device turns wheels. For example, the steering device includes an electric power steering (EPS) device. The driving device is a power source that generates a driving force. Examples of the drive device include an engine, an electric motor, an in-wheel motor, and the like. The braking device generates a braking force.

The control device 105 is a computer that controls the vehicle 100. The control device 105 includes one or more processors 106 (hereinafter simply referred to as a processor 106) and one or more memory devices 107 (hereinafter simply referred to as a memory device 107). The processor 106 executes a variety of processing. For example, the processor 106 includes a central processing unit (CPU). The memory device 107 stores a variety of information necessary for the processing by the processor 106. Examples of the memory device 107 include a volatile memory, a non-volatile memory, a hard disk drive (HDD), a solid state drive (SSD), and the like. The control device 105 may include one or more electronic control units (ECUs).

A vehicle control program PROG1 is a computer program executed by the processor 106. The functions of the control device 105 are implemented by the processor 106 executing the vehicle control program PROG1. The vehicle control program PROG1 is stored in the memory device 107. The vehicle control program PROG1 may be recorded on a non-transitory computer-readable recording medium.

### 3-2. Sensor-Detected Information

The control device 105 uses the sensor group 102 to acquire the sensor-detected information SEN. The sensor-detected information SEN is stored in the memory device 107.

The sensor-detected information SEN includes surrounding situation information indicating a result of recognition by the recognition sensor. For example, the surrounding situation information includes the image information IMG captured by the camera. The surrounding situation information may include information regarding an object around the vehicle 100. Examples of the object around the vehicle 100 include the obstacle 500, a white line, a traffic light, a sign, a roadside structure, and the like. Examples of the obstacle 500 include another vehicle (a preceding vehicle, an adjacent vehicle, a following vehicle, and the like), a motor bike, a bicycle, a pedestrian, and the like. The information regarding the object around the vehicle 100 indicates a relative position and a relative velocity of the object with respect to the vehicle 100.

In addition, the sensor-detected information SEN includes vehicle state information indicating the vehicle state detected by the vehicle state sensor.

Furthermore, the sensor-detected information SEN includes vehicle position information indicating the position and the orientation of the vehicle 100. The vehicle position information is acquired by the position sensor. Highly accurate vehicle position information may be acquired by performing a well-known localization using map information and the surrounding situation information (the object information).

### 3-3. Vehicle Travel Control

The control device 105 executes vehicle travel control that controls travel of the vehicle 100. The vehicle travel control includes steering control, driving control, and braking control. The control device 105 executes the vehicle travel control by controlling the travel device 103 (i.e., the steering device, the driving device, and the braking device).

The control device 105 may execute autonomous driving control based on the sensor-detected information SEN. More specifically, the control device 105 generates a travel plan of the vehicle 100 based on the sensor-detected information SEN. Further, the control device 105 generates, based on the sensor-detected information SEN, a target trajectory required for the vehicle 100 to travel in accordance with the travel plan. The target trajectory includes a target position and a target speed. Then, the control device 105 executes the vehicle travel control such that the vehicle 100 follows the target trajectory.

### 3-4. Processing Related to Remote Operation

When the remote operation of the vehicle 100 is performed, the control device 105 communicates with the remote operator terminal 200 via the communication device 101.

The control device 105 transmits at least a part of the sensor-detected information SEN to the remote operator terminal 200. In particular, the sensor-detected information SEN transmitted to the remote operator terminal 200 includes the object information OBJ regarding the object group being the simulation target.

More specifically, the object information OBJ includes the vehicle information VCL regarding the vehicle 100. The vehicle information VCL includes at least the vehicle position information. The vehicle information VCL may include the vehicle state information (e.g., a speed, a steering angle, and the like).

The object information OBJ may include the obstacle information OBS regarding each obstacle 500 around the vehicle 100. The obstacle information OBS indicates at least a position of the obstacle 500. The position of obstacle 500 can be calculated based on the position of vehicle 100 and the relative position of obstacle 500 with respect to vehicle 100. The obstacle information OBS may indicate a state (e.g., a speed, a steering angle, and the like) of the obstacle 500. For example, the speed of the obstacle 500 can be calculated based on a history of the position of the obstacle 500. The steering angle of the obstacle 500 can be estimated based on the history of the position of the obstacle 500. The position and the state of the obstacle 500 (another vehicle) may be acquired through a vehicle-to-vehicle communication.

The sensor-detected information SEN transmitted to the remote operator terminal 200 may include the image information IMG captured by the camera.

Furthermore, the control device 105 receives the remote operation information OPE from the remote operator terminal 200. The remote operation information OPE is information regarding the remote operation by the remote operator O. For example, the remote operation information OPE includes the amount of operation performed by the remote operator O. The control device 105 performs the vehicle travel control in accordance with the received remote operation information OPE.

### 4. Example of Remote Operator Terminal

### 4-1. Configuration Example

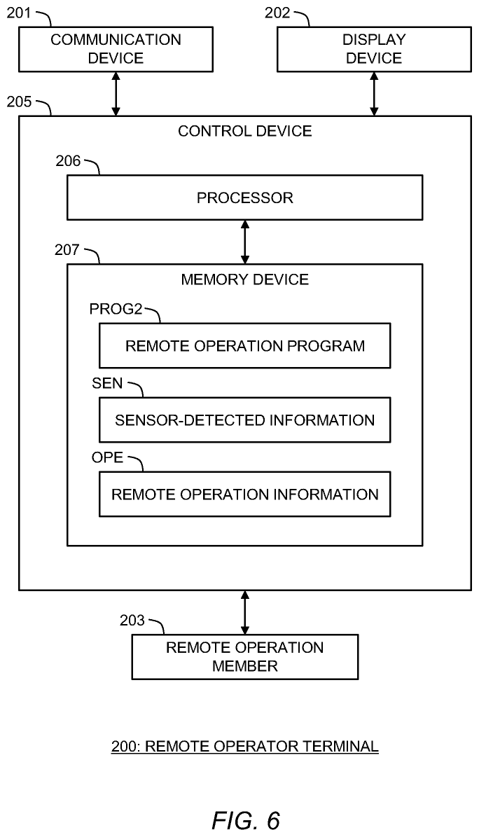

FIG. 6 is a block diagram showing a configuration example of the remote operator terminal 200. The remote operator terminal 200 includes a communication device 201, a display device 202, a remote operation member 203, and a control device (controller) 205.

The communication device 201 communicates with the vehicle 100 and the management device 300. In addition, the communication device 201 communicates with the infrastructure sensor 400 (see FIG. 3).

The display device 202 presents a variety of information to the remote operator O by displaying the variety of information.

The remote operation member 203 is a member operated by the remote operator O when remotely operating the vehicle 100. The remote operation member 203 includes a steering wheel, an accelerator pedal, a brake pedal, a direction indicator, and the like.

The control device 205 controls the remote operator terminal 200. The control device 205 includes one or more processors 206 (hereinafter simply referred to as a processor 206) and one or more memory devices 207 (hereinafter simply referred to as a memory device 207). The processor 206 executes a variety of processing. For example, the processor 206 includes a CPU. The memory device 207 stores a variety of information necessary for the processing by the processor 206. Examples of the memory device 207 include a volatile memory, a non-volatile memory, an HDD, an SSD, and the like.

A remote operation program PROG2 is a computer program executed by the processor 206. The functions of the control device 205 are implemented by the processor 206 executing the remote operation program PROG2. The remote operation program PROG2 is stored in the memory device 207. The remote operation program PROG2 may be recorded on a non-transitory computer-readable recording medium. The remote operation program PROG2 may be provided via a network.

The control device 205 communicates with vehicle 100 via communication device 201. The control device 205 receives the sensor-detected information SEN transmitted from the vehicle 100.

In addition, the control device 205 may communicate with the infrastructure sensor 400 (see FIG. 3) via the communication device 201. The infrastructure sensor 400 (for example, an infrastructure camera) acquires the obstacle information OBS regarding the obstacle 500 around the vehicle 100. The control device 205 receives the obstacle information OBS transmitted from the infrastructure sensor 400.

The remote operator O operates the remote operation member 203. The amount of operation of the remote operation member 203 is detected by a sensor provided in the remote operation member 203. The control device 205 generates the remote operation information OPE reflecting the amount of operation of the remote operation member 203 performed by the remote operator O. Then, the control device 205 transmits the remote operation information OPE to the vehicle 100 via the communication device 201.

### 4-2. Simulator

The remote operator terminal 200 according to the present embodiment includes the simulator 240. The simulator 240 is realized by a cooperation of the processor 206 executing the remote operation program PROG2 and the memory device 207.

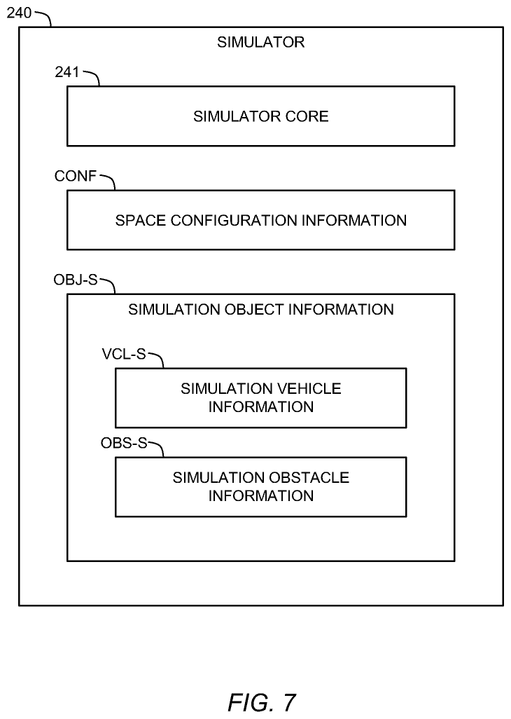

FIG. 7 is a block diagram for explaining the simulator 240. The simulator 240 includes a simulator core 241. The simulator core 241 executes in real time a simulation of the object group including the vehicle 100 in a predetermined space. Typically, the predetermined space is a space of a fixed area. For example, the predetermined space is a “certain city” such as a smart city. The object group being the simulation target may include the obstacle 500 around the vehicle 100 in addition to the vehicle 100.

Space configuration information CONF indicates a three-dimensional configuration of the predetermined space. In particular, the space configuration information CONF indicates a three-dimensional configuration of a background other than the obstacle 500 in the predetermined space. The background includes roads, white lines, traffic lights, signs, roadside structures, buildings, and the like.

Simulation object information OBJ-S is the object information OBJ used in the simulation. The simulation object information OBJ-S includes “simulation vehicle information VCL-S” that is the vehicle information VCL used in the simulation. The simulation object information OBJ-S may further include “simulation obstacle information OBS-S” that is the obstacle information OBS used in the simulation.

The simulator 240 (the simulator core 241) executes the simulation based on the space configuration information CONF and the simulation object information OBJ-S to estimate the simulation object information OBJ-S of the next cycle. Such the simulator 240 is realized by, for example, the digital twin technique.

The control device 205 displays a result of the simulation by the simulator 240 on the display device 202 (see FIG. 4).

### 5. Processing by Remote Operator Terminal in Second Mode

### 5-1. Functional Configuration Example

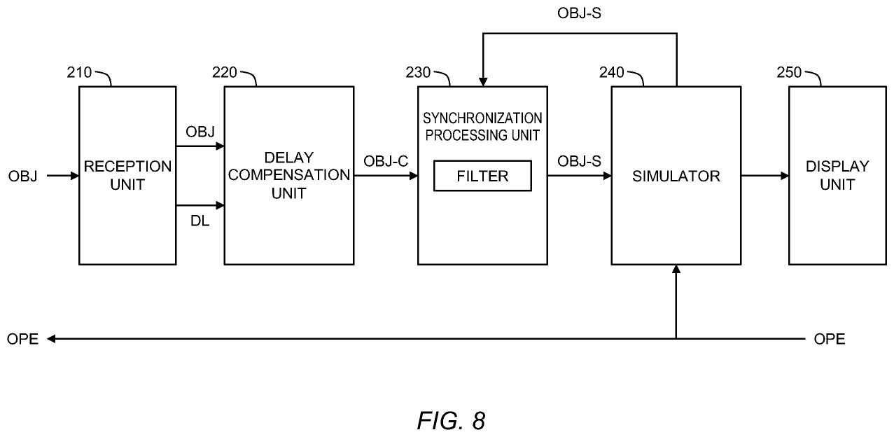

FIG. 8 is a block diagram showing a functional configuration example of the remote operator terminal 200 in the second mode. The remote operator terminal 200 includes a reception unit 210, a delay compensation unit 220, a synchronization processing unit 230, the simulator 240, and a display unit 250 as functional blocks. These functional blocks are realized by the communication device 201, the display device 202, and the control device 205.

The reception unit 210 receives the object information OBJ through the communication with the outside during the remote operation of the vehicle 100. The object information OBJ is transmitted from the vehicle 100 to the remote operator terminal 200. The object information OBJ may be transmitted from the infrastructure sensor 400 to the remote operator terminal 200. The reception unit 210 grasps a state of the communication between the vehicle 100 and the remote operator terminal 200 based on a result of reception of the object information OBJ. Examples of the communication state include a delay amount DL, a communication speed, a radio wave reception intensity, and the like.

The delay compensation unit 220 executes a “delay compensation process.” More specifically, the delay compensation unit 220 acquires the object information OBJ and the information of the delay amount DL from the reception unit 210. The delay amount DL is not constant but varies depending on the communication state. The delay compensation unit 220 compensates for the delay of the received object information OBJ based on the delay amount DL. The object information OBJ whose delay is compensated for is hereinafter referred to as “corrected object information OBJ-C.” It can be said that the delay compensation unit 220 calculates the corrected object information OBJ-C by compensating for the delay of the object information OBJ based on the delay amount DL. The corrected object information OBJ-C includes “corrected vehicle information VCL-C” that is the vehicle information VCL whose delay is compensated for. The corrected object information OBJ-C may include “corrected obstacle information OBS-C” that is the obstacle information OBS whose delay is compensated for. A concrete example of the delay compensation process will be described in the following Section 5-2.

As described above, the simulator 240 executes in real time the simulation of the object group in the predetermined space. An initial value of each object in the simulation is set based on initial corrected object information OBJ-C. The simulation object information OBJ-S is the object information OBJ in the simulation. The simulation object information OBJ-S includes the simulation vehicle information VOL-S that is the vehicle information VCL in the simulation. The simulation object information OBJ-S may further include the simulation obstacle information OBS-S that is the obstacle information OBS in the simulation.

The synchronization processing unit 230 executes a “synchronization process.” More specifically, the synchronization processing unit 230 corrects the simulation object information OBJ-S based on the corrected object information OBJ-C. Typically, the synchronization processing unit 230 corrects the simulation object information OBJ-S so as to be consistent with (synchronized with) the corrected object information OBJ-C. For example, the synchronization processing unit 230 corrects the simulation vehicle information VCL-S so as to be consistent with (synchronized with) the corrected vehicle information VCL-C. The synchronization processing unit 230 may correct the simulation obstacle information OBS-S so as to be consistent with (synchronized with) the corrected obstacle information OBS-C.

As a result of the correction of the simulation object information OBJ-S, the simulation object information OBJ-S may suddenly change. For example, the position of the vehicle 100 in the simulation may jump discontinuously. As another example, the vehicle 100 in the simulation may rapidly accelerate. In order to suppress such a sudden change in the simulation object information OBJ-S, a filtering process may be performed. More specifically, the synchronization processing unit 230 includes a filter for suppressing the sudden change in the simulation object information OBJ-S. Examples of the filter include a first order lag filter such as a low-pass filter. The synchronization processing unit 230 gradually changes the simulation object information OBJ-S so as to become consistent with the corrected object information OBJ-C by applying the filter to the simulation object information OBJ-S.

It should be noted that a communication cycle of the object information OBJ is longer than a simulation cycle of the simulator 240. In other words, a simulation frequency of the simulator 240 is higher than a communication frequency of the object information OBJ. Therefore, basically, the simulation object information OBJ-S is updated only by the simulation. However, when the remote operator terminal 200 receives the object information OBJ, the corrected object information OBJ-C is updated, and thus the simulation object information OBJ-S is corrected based on the latest corrected object information OBJ-C.

The display unit 250 displays the result of the simulation by the simulator 240 on the display device 202 (see FIG. 4). The simulation result screen displayed on the display device 202 visually represents the object group (i.e., the vehicle 100 and the obstacle 500) in the predetermined space. For example, the simulation result screen three dimensionally represents the object group and a background in the predetermined space. The simulation result screen may reproduce and represent a view as seen from the vehicle 100. The simulation result screen is updated at each simulation cycle.

The remote operator O operates the remote operation member 203 to perform the remote operation of the vehicle 100 while viewing the simulation result screen displayed on the display device 202. The remote operation information OPE includes information reflecting the amount of operation performed by the remote operator O. The remote operation information OPE is transmitted to the vehicle 100 and reflected in the vehicle travel control. In addition, the remote operation information OPE is also fed back to the simulator 240. The simulator 240 reflects the amount of operation performed by the remote operator O in the simulation. That is, the simulator 240 calculates the simulation object information OBJ-S (in particular, the simulation vehicle information VCL-S) so as to reflect the amount of operation performed by the remote operator O. In other words, the simulator 240 executes the simulation while reflecting the amount of operation performed by the remote operator O in the simulation vehicle information VCL-S.

### 5-2. Delay Compensation Process

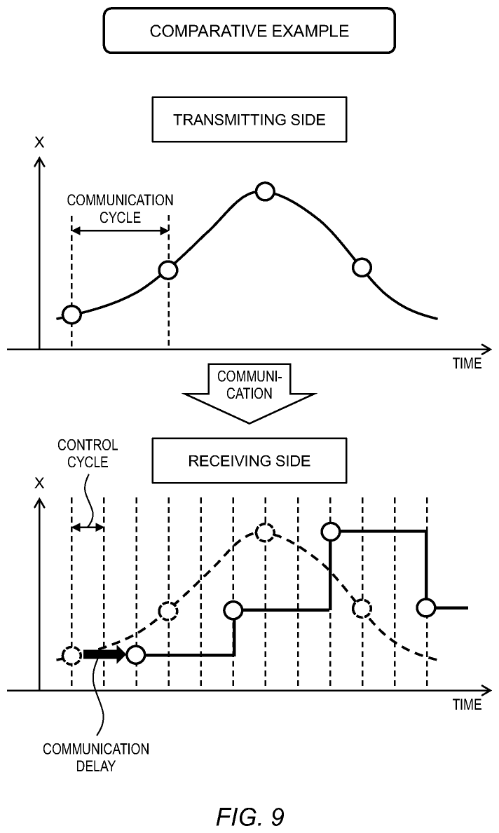

FIG. 9 is a conceptual diagram for explaining a delay in the remote operation system 1. A horizontal axis represents time, and a vertical axis represents “information X” communicated between the vehicle 100 and the remote operator terminal 200. An upper diagram of FIG. 9 illustrates a time variation of the information X on the transmitting side. A circle in the upper diagram indicates the information X transmitted from the transmitting side and a transmission timing thereof. On the other hand, a lower diagram illustrates a time variation of the information X used on the receiving side. A circle in the lower diagram indicates the information X received by the receiving side and a reception timing thereof.

The communication between the vehicle 100 and the remote operator terminal 200 is accompanied by the communication delay. The delay amount DL is not constant but varies depending on the communication state. As shown in FIG. 9, the information X on the receiving side is delayed from the information X on the transmitting side by the delay amount DL.

Generally, as shown in FIG. 9, a communication cycle of the information X is longer than a control cycle on the receiving side. In other words, a control frequency is higher than a communication frequency of the information X. Therefore, the information X used for the control on the receiving side deviates from the actual information X on the transmitting side. As a difference between the communication cycle and the control cycle increases, the deviation of the information X increases. Further, as the delay amount DL of the communication increases, the deviation of the information X increases.

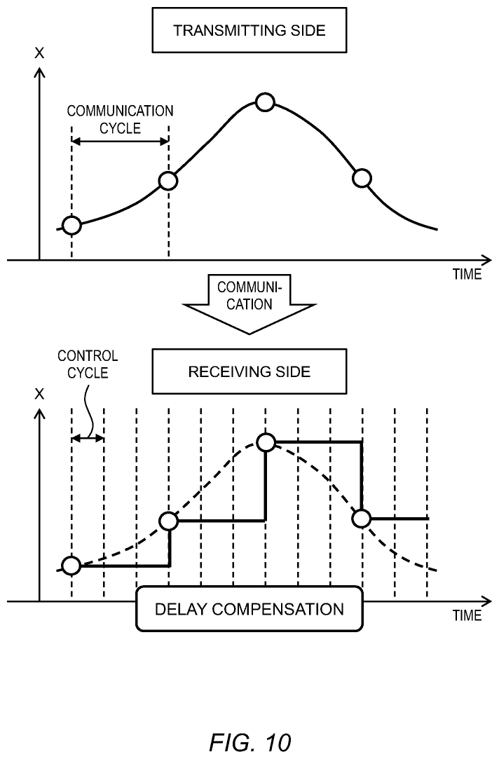

FIG. 10 is a conceptual diagram for explaining the “delay compensation process.” The receiving side compensates for the delay of the information X received from the transmitting side. This process is the delay compensation process. More specifically, the receiving side acquires information of the delay amount DL of the communication based on a result of reception of the information X from the transmitting side. Then, the receiving side compensates for the delay of the information X based on the delay amount DL.

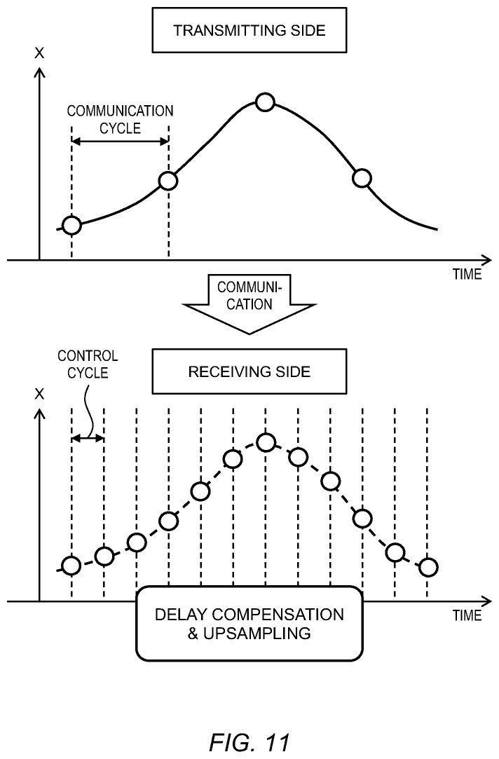

FIG. 11 is a conceptual diagram for explaining an “upsampling process.” The receiving side may increase a sampling frequency (sampling rate) of the information X by estimating (predicting) the information X in a non-sampling period. This process is the upsampling process. In particular, the receiving side performs the upsampling process such that a difference between the sampling cycle (the sampling frequency) of the information X and the control cycle (the control frequency) becomes smaller than the difference between the communication cycle (the communication frequency) and the control cycle (the control frequency). For example, the receiving side performs the upsampling process such that the sampling cycle (the sampling frequency) of the information X coincides with the control cycle (the control frequency).

In the case of the delay compensation process in the remote operator terminal 200, the information X is the object information OBJ. The delay compensation unit 220 of the remote operator terminal 200 compensates for the delay of the object information OBJ based on the delay amount DL to calculate the corrected object information OBJ-C. Hereinafter, examples of the delay compensation unit 220 of the remote operator terminal 200 will be described.

### 5-2-1. First Example

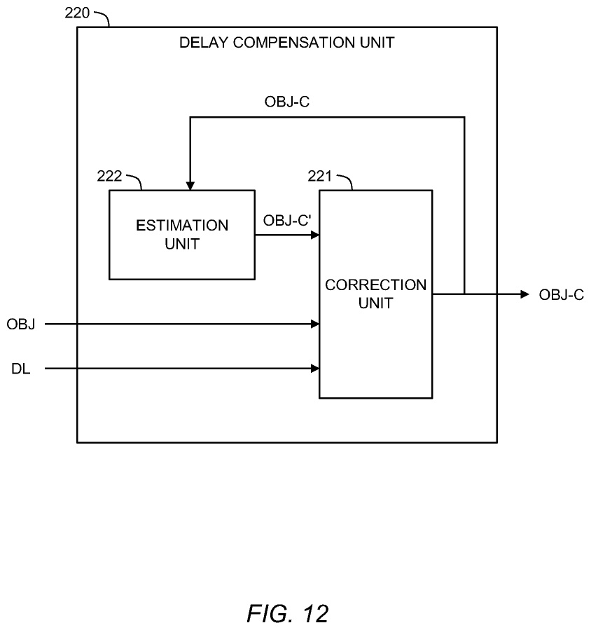

FIG. 12 is a block diagram showing a first example of the delay compensation unit 220. The delay compensation unit 220 in the first example is configured to perform the delay compensation process while performing the upsampling process. More specifically, the delay compensation unit 220 includes a correction unit 221 and an estimation unit 222.

The correction unit 221 acquires the object information OBJ (actual value) and the information on the delay amount DL from the reception unit 210. The correction unit 221 outputs the corrected object information OBJ-C.

The corrected object information OBJ-C is fed back to the estimation unit 222. The estimation unit 222 estimates (predicts) the corrected object information OBJ-C in the non-sampling period based on the corrected object information OBJ-C. That is, the estimation unit 222 performs the upsampling process. For example, the estimation unit 222 holds an equation of motion representing a motion of the objects. The estimation unit 222 estimates (predicts) the corrected object information OBJ-C at the next timing based on the equation of motion and a previous value of the corrected object information OBJ-C.

The corrected object information OBJ-C estimated by the estimation unit 222 is referred to as corrected object information OBJ-C′ for convenience sake. The corrected object information OBJ-C′ estimated by the estimation unit 222 is input to the correction unit 221. The correction unit 221 basically outputs the corrected object information OBJ-C′ as the corrected object information OBJ-C. The corrected object information OBJ-C is fed back to the estimation unit 222 again.

However, the corrected object information OBJ-C′ estimated by the estimation unit 222 includes an estimation error. Therefore, the correction unit 221 corrects the estimation error of the corrected object information OBJ-C′ as appropriate. More specifically, the correction unit 221 acquires the object information OBJ (actual value) and the information on the delay amount DL from the reception unit 210. The correction unit 221 corrects the estimation error of the corrected object information OBJ-C′ while compensating for the delay based on the object information OBJ (actual value) and the delay amount DL. As a result, the corrected object information OBJ-C in which the delay is compensated for and the estimation error is corrected is acquired. The corrected object information OBJ-C is fed back to the estimation unit 222 again.

It should be noted that since the communication cycle of the object information OBJ is longer than the control cycle of the delay compensation unit 220, the object information OBJ is input to the correction unit 221 at a lower frequency than the corrected object information OBJ-C′. Therefore, the correction unit 221 basically outputs the corrected object information OBJ-C′ as the corrected object information OBJ-C. When the object information OBJ is updated, the correction unit 221 corrects the estimation error of the corrected object information OBJ-C′ based on the latest object information OBJ and the delay amount DL to acquire the corrected object information OBJ-C.

As described above, the delay compensation unit 220 shown in FIG. 12 performs the delay compensation process while performing the upsampling process. The delay compensation unit 220 performing the upsampling process and the delay compensation process can be realized by using, for example, a delayed Kalman filter. The delayed Kalman filter is also called OOSM (Out-of-Sequence Measurement). For details of the delayed Kalman filter, refer to Non-Patent Literature 1 and Non-Patent Literature 2. The delayed Kalman filter is also applicable to the object information OBJ whose delay amount DL varies. The delay compensation unit 220 performs the upsampling process and the delay compensation process by applying a delayed Kalman filter to the object information OBJ whose delay amount DL varies.

### 5-2-2. Second Example

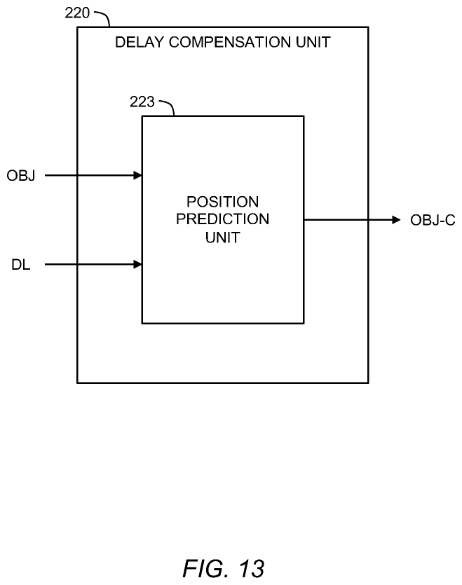

FIG. 13 is a block diagram showing a second example of the delay compensation unit 220. The delay compensation unit 220 includes a position prediction unit 223. The position prediction unit 223 acquires the object information OBJ and the information on the delay amount DL from the reception unit 210. The object information OBJ includes a position, a speed, and a steering angle of the object. The position prediction unit 223 predicts a future trajectory of the object based on the object information OBJ. Then, based on the future trajectory of the object and the delay amount DL, the position prediction unit 223 prefetches the position of the object by the delay amount DL. That is, the position prediction unit 223 compensates for the delay of the position of the object indicated by the object information OBJ to acquire the corrected object information OBJ-C.

### 5-3. Effects

As described above, the remote operator terminal 200 includes the simulator 240 that executes in real time the simulation of the object group including the vehicle 100 being the target of the remote operation. The remote operator terminal 200 displays the result of simulation on the display device 202. The remote operator O is able to perform the remote operation of the vehicle 100 by referring to the displayed result of the simulation.

The simulation (the second loop LOOP-2) executed in the remote operator terminal 200 does not depend on a condition of the communication between the vehicle 100 and the remote operator terminal 200. Therefore, the remote operator O is able to perform the remote operation of the vehicle 100 without being affected by the communication delay and the information loss. As a result, a delay in decision by the remote operator O, an awkward remote operation, and the like are suppressed. That is, the remote operator O is able to perform the remote operation of the vehicle 100 more smoothly and more safely.

Furthermore, according to the present embodiment, the remote operator terminal 200 receives the object information OBJ on the object group being the simulation target in parallel with the execution of the simulation. The object information OBJ indicates at least the position of the object group. The remote operator terminal 200 performs the “delay compensation process” that compensates for the delay of the received object information OBJ to acquire the corrected object information OBJ-C. Furthermore, the remote operator terminal 200 performs the “synchronization process” that corrects the simulation object information OBJ-S based on the corrected object information OBJ-C. As a result, the simulation accuracy is secured and the accuracy of the remote operation is also secured.

The synchronization process may include the filtering process for gradually changing the simulation object information OBJ-S so as to become consistent with the corrected object information OBJ-C. As a result, a sudden change in the simulation object information OBJ-S is suppressed. For example, the position of the vehicle 100 in the simulation is prevented from jumping discontinuously.

### 6. Switching Process

In a scene where a behavior of the vehicle 100 changes in a complicated manner, prediction accuracy of the behavior of the vehicle 100 may decrease. When the prediction accuracy is low, the second mode may be temporarily suspended. In this case, the operation mode of the remote operation system 1 (the remote operator terminal 200) is switched to a “temporary mode.” This process is hereinafter referred to as a “switching process.”

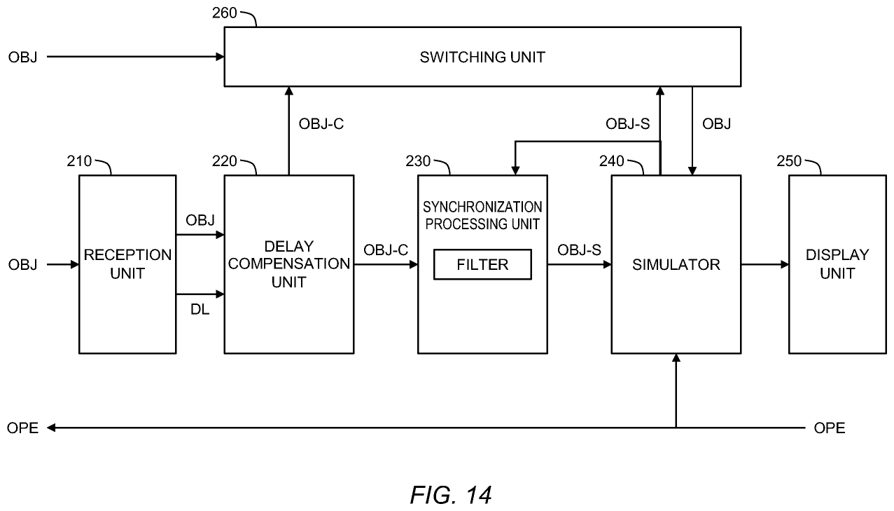

FIG. 14 is a block diagram for explaining the switching process. The remote operator terminal 200 further includes a switching unit 260 in addition to the configuration shown in FIG. 8.

The switching unit 260 receives the corrected object information OBJ-C from the delay compensation unit 220 and receives the simulation object information OBJ-S from the simulator 240. The switching unit 260 calculates a degree of difference between the corrected object information OBJ-C and the simulation object information OBJ-S. For example, the switching unit 260 calculates an absolute value of a difference for each parameter between the corrected object information OBJ-C and the simulation object information OBJ-S for each object being the simulation target. Then, the switching unit 260 calculates, as the degree of difference, a sum of the absolute values of the difference for each object and for each parameter.

Furthermore, the switching unit 260 determines whether or not a state in which the calculated degree of difference exceeds a threshold continues for a predetermined period of time or more. When the state in which the degree of difference exceeds the threshold continues for the predetermined period of time or more, the switching unit 260 provides the object information OBJ to the simulator 240. The simulator 240 sets not the corrected object information OBJ-C but the object information OBJ as the simulation object information OBJ-S.

When the switching process is performed, the remote operator terminal 200 may instruct the vehicle 100 to decelerate. The vehicle 100 decelerates in accordance with the instruction from remote operator terminal 200. Accordingly, it is expected that the prediction accuracy of the behavior of the vehicle 100 is improved.

When a state in which the degree of difference is equal to or less than the threshold continues for a predetermined period of time or more, the switching unit 260 stops providing the object information OBJ to the simulator 240. The operation mode of the remote operation system 1 (the remote operator terminal 200) returns to the second mode.

### 7. Delay Compensation Process on Vehicle Side

The remote operator terminal 200 transmits the remote operation information OPE including the amount of operation performed by the remote operator O to the vehicle 100. The control device 105 of the vehicle 100 receives the remote operation information OPE transmitted from the remote operator terminal 200. Compensating for the delay of the remote operation information OPE as well makes it possible for the remote operator O to further smoothly perform the remote operation of the vehicle 100.

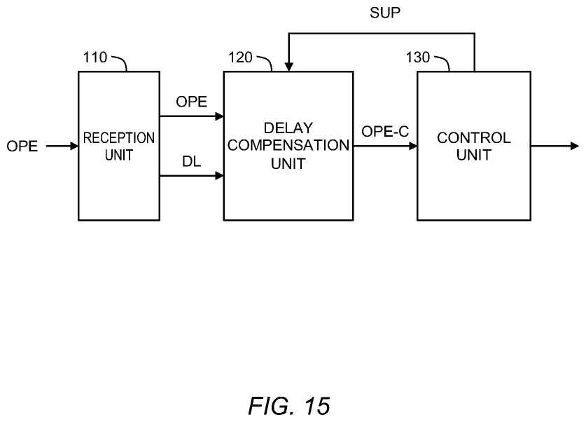

FIG. 15 is a block diagram showing a functional configuration example related to a delay compensation process in the vehicle 100. The vehicle 100 includes a reception unit 110, a delay compensation unit 120, and a control unit 130 as functional blocks. These functional blocks are realized by the communication device 101 and the control device 105.

The reception unit 110 receives the remote operation information OPE transmitted from the remote operator terminal 200 during the remote operation of the vehicle 100. The reception unit 110 grasps a state of the communication with the remote operator terminal 200 based on a result of reception of the remote operation information OPE. Examples of the communication state include a delay amount DL, a communication speed, a radio wave reception intensity, and the like.

The delay compensation unit 120 executes the delay compensation process. More specifically, the delay compensation unit 120 acquires the remote operation information OPE and the information on the delay amount DL from the reception unit 110. The delay amount DL is not constant but varies depending on the communication state. The delay compensation unit 120 compensates for the delay of the remote operation information OPE based on the delay amount DL. Hereinafter, the remote operation information OPE whose delay is compensated for is referred to as a “corrected remote operation information OPE-C.” It can be said that the delay compensation unit 120 calculates the corrected remote operation information OPE-C by compensating for the delay of the remote operation information OPE based on the delay amount DL.

The control unit 130 receives the corrected remote operation information OPE-C after the delay compensation process. The control unit 130 performs the vehicle travel control in accordance with the corrected remote operation information OPE-C.

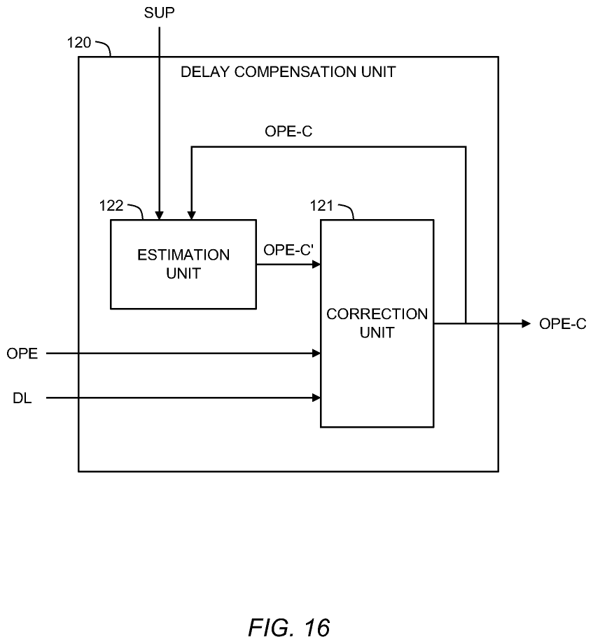

FIG. 16 is a block diagram showing an example of the delay compensation unit 120. The delay compensation unit 120 shown in FIG. 16 is configured to perform the delay compensation process while performing the upsampling process (see FIGS. 10 and 11). More specifically, the delay compensation unit 120 includes a correction unit 121 and an estimation unit 122.

The correction unit 121 acquires the remote operation information OPE (actual value) and the information on the delay amount DL from the reception unit 110. The correction unit 121 outputs corrected remote operation information OPE-C.

The corrected remote operation information OPE-C is fed back to the estimation unit 122. The estimation unit 122 estimates (predicts) the corrected remote operation information OPE-C in the non-sampling period based on the corrected remote operation information OPE-C. That is, the estimation unit 122 performs the upsampling process. For example, the estimation unit 122 holds an equation of motion representing a motion of the vehicle 100. The estimation unit 122 estimates (predicts) the corrected remote operation information OPE-C at the next timing based on the equation of motion and a previous value of the corrected remote operation information OPE-C.

The corrected remote operation information OPE-C estimated by the estimation unit 122 is referred to as corrected remote operation information OPE-C′ for convenience sake. The corrected remote operation information OPE-C′ estimated by the estimation unit 122 is input to the correction unit 121. The correction unit 121 basically outputs the corrected remote operation information OPE-C′ as the corrected remote operation information OPE-C. The corrected remote operation information OPE-C is fed back to the estimation unit 122 again.

However, the corrected remote operation information OPE-C′ estimated by the estimation unit 122 includes an estimation error. Therefore, the correction unit 121 corrects the estimation error of the corrected remote operation information OPE-C′ as appropriate. More specifically, the correction unit 121 acquires the remote operation information OPE (actual value) and the information on the delay amount DL from the reception unit 110. The correction unit 121 corrects the estimation error of the corrected remote operation information OPE-C′ while compensating for the delay based on the remote operation information OPE (actual value) and the delay amount DL. As a result, the corrected remote operation information OPE-C in which the delay is compensated for and the estimation error is corrected is acquired. The corrected remote operation information OPE-C is fed back to the estimation unit 122 again.

It should be noted that since the communication cycle of the remote operation information OPE is longer than the control cycle of the delay compensation unit 120, the remote operation information OPE is input to the correction unit 121 at a lower frequency than the corrected remote operation information OPE-C′. Therefore, the correction unit 121 basically outputs the corrected remote operation information OPE-C′ as the corrected remote operation information OPE-C. When the remote operation information OPE is updated, the correction unit 121 corrects the estimation error of the corrected remote operation information OPE-C′ based on the latest remote operation information OPE and the delay amount DL to acquire the corrected remote operation information OPE-C.

As described above, the delay compensation unit 120 shown in FIG. 16 performs the delay compensation process while performing the upsampling process. The delay compensation unit 120 performing the upsampling process and the delay compensation process can be realized by using, for example, a delayed Kalman filter (see Non-Patent Literature 1 and Non-Patent Literature 2). The delayed Kalman filter is also applicable to the remote operation information OPE whose delay amount DL varies. The delay compensation unit 120 executes the upsampling process and the delay compensation process by applying a delayed Kalman filter to the remote operation information OPE whose delay amount DL varies.

Supplementary information SUP may be used for improving accuracy of the estimation of the corrected remote operation information OPE-C′ by the estimation unit 122. For example, the supplementary information SUP includes a shape of a road on which the vehicle 100 moves. For example, when the vehicle 100 travels on a curved road, information on the shape of the curved road is used for estimating a future operation amount. The road shape is acquired, for example, from the surrounding situation information. Alternatively, the road shape may be acquired from the vehicle position information and map information. The supplementary information SUP may include a vehicle travel control amount which is a control amount of the travel device 103 (actuators) of the vehicle 100. The vehicle travel control amount also is useful for the estimation process by the estimation unit 122. The supplementary information SUP is provided from the control unit 130 to the delay compensation unit 120. The estimation unit 122 estimates (predicts) the corrected remote operation information OPE-C′ in consideration of the supplementary information SUP as well. Thus, the estimation accuracy of the corrected remote operation information OPE-C′ is further improved.

What is claimed is:

1. A remote operation system comprising:
a moving body being a target of a remote operation performed by a remote operator; and
a remote operator terminal on a side of the remote operator, wherein
the remote operator terminal includes a simulator executing in real time a simulation of an object group including the moving body in a predetermined space, and is configured to display a result of the simulation, and
in parallel with execution of the simulation, the remote operator terminal is further configured to:
perform a communication with at least the moving body to receive object information indicating at least a position of the object group;
execute a delay compensation process that compensates for a delay of the received object information to acquire corrected object information; and
execute a synchronization process that corrects simulation object information, which is the object information in the simulation, based on the corrected object information.

2. The remote operation system according to claim 1, wherein
the simulator calculates the simulation object information so as to reflect an amount of operation performed by the remote operator.

3. The remote operation system according to claim 1, wherein
the synchronization process includes correcting the simulation object information so as to be consistent with the corrected object information.

4. The remote operation system according to claim 3, wherein
the synchronization process includes a filtering process that gradually changes the simulation object information so as to become consistent with the corrected object information.

5. The remote operation system according to claim 1, wherein
the delay compensation process includes:
estimating the corrected object information; and
correcting an estimation error of the corrected object information while compensating for the delay based on the received object information and a delay amount of communication from the moving body to the remote operator terminal, to acquire the corrected object information.

6. The remote operation system according to claim 5, wherein
the remote operator terminal is configured to execute the delay compensation process by applying a delayed Kalman filter to the object information.

7. The remote operation system according to claim 1, wherein
the object group includes the moving body and an obstacle around the moving body.

8. The remote operation system according to claim 1, wherein
the remote operator terminal is further configured to set the object information acquired through the communication as the simulation object information, when a state in which a degree of difference between the simulation object information and the corrected object information exceeds a threshold continues for a predetermined period of time or more.

9. The remote operation system according to claim 8, wherein
the remote operator terminal is further configured to instruct the moving body to decelerate, when the state in which the degree of difference between the simulation object information and the corrected object information exceeds the threshold continues for the predetermined period of time or more.

10. The remote operation system according to claim 1, wherein
the moving body is configured to:
receive remote operation information including an amount of operation performed by the remote operator from the remote operator terminal;
compensate for a delay of the received remote operation information to acquire corrected remote operation information; and
control the moving body in accordance with the corrected remote operation information.

11. A remote operator terminal used by a remote operator performing a remote operation of a moving body,
the remote operator terminal comprising one or more processors configured to:
execute in real time a simulation of an object group including the moving body in a predetermined space; and
display a result of the simulation, wherein
in parallel with execution of the simulation, the one or more processors are further configured to:
perform a communication with at least the moving body to receive object information indicating at least a position of the object group;
execute a delay compensation process that compensates for a delay of the received object information to acquire corrected object information; and
execute a synchronization process that corrects simulation object information, which is the object information in the simulation, based on the corrected object information.
